(19) United States
(12) Patent Application Publication
(10) Pub. No.: US 2015/0253659 A1
(43) Pub. Date: Sep. 10, 2015

(54) MASK AND PATTERN FORMING METHOD

(71) Applicant: KABUSHIKI KAISHA TOSHIBA, Tokyo (JP)

(72) Inventors: RYOICHI Inanami, Yokohama Kanagawa (JP); Shinichi Ito, Yokohama Kanagawa (JP); Takashi Sato, Fujisawa Kanagawa (JP)

(21) Appl. No.: 14/464,322

(22) Filed: Aug. 20, 2014

(30) Foreign Application Priority Data
Mar. 7, 2014 (JP) 2014-044725

(51) Int. Cl. G03F 1/38; G03F 7/20

(52) U.S. Cl. CPC G03F 1/38; G03F 7/20

(57) ABSTRACT

According to one embodiment, a mask includes a first pattern portion and an intermediate member. The first pattern portion includes a plurality of first light transmission parts disposed periodically and having transmittivity with respect to light, and first shielding parts provided between each of the plurality of first light transmission parts and having a transmittance with respect to the light lower than a transmittance of the plurality of first light transmission parts. The intermediate member is provided on the first pattern portion. The intermediate member has a thickness in accordance with the wavelength of the light and a first period of the first light transmission parts.

### CROSS-REFERENCE TO RELATED APPLICATIONS

This application is based upon and claims the benefit of priority from Japanese Patent Application No.2014-044725, filed on Mar. 7, 2014; the entire contents of which are incorporated herein by reference.

### FIELD

Embodiments described herein relate generally to a mask and a pattern forming method

### BACKGROUND

A fine pattern can be formed by the proximity method using Talbot interference, without using an expensive projection light exposure device. In this type of pattern forming method using the proximity exposure, the mask surface and the wafer surface are separated by a predetermined distance, and the wafer is exposed to light at a predetermined position in the direction that the light is traveling, in order to form a fine pattern on the wafer. As the transferred patterns become more refined, it is desirable to increase the accuracy of setting the position of the wafer.

### BRIEF DESCRIPTION OF THE DRAWINGS

FIG. 1 is a flowchart illustrating a pattern forming method according to a first embodiment;

FIG. 2 is a schematic view illustrating a light exposure device according to the first embodiment;

FIG. 3 is a drawing illustrating Talbot interference;

FIG. 4 is a schematic view illustrating a light exposure device according to a second embodiment;

FIGS. 5A to 5C are schematic cross-sectional views illustrating the fabrication of the mask;

FIGS. 6A to 6E are a flowchart illustrating the fabrication of the mask;

FIGS. 7A to 7J are a flowchart illustrating the fabrication of a mask;

FIGS. 8A to 8I are a flowchart illustrating the fabrication of a mask;

FIGS. 9A to 9I are a flowchart illustrating the fabrication of a mask;

FIGS. 10A to 10F are a flowchart illustrating the fabrication of a mask;

FIGS. 11A to 11G are a flowchart illustrating the fabrication of a mask; and

FIGS. 12A to 12G are a flowchart illustrating a pattern forming method according to a second embodiment.

### DETAILED DESCRIPTION

According to one embodiment, a mask includes a first pattern portion and an intermediate member. The first pattern portion includes a plurality of first light transmission parts disposed periodically and having transmittivity with respect to light, and first shielding parts provided between each of the plurality of first light transmission parts and having a transmittance with respect to the light lower than a transmittance of the plurality of first light transmission parts. The intermediate member is provided on the first pattern portion. The intermediate member has a thickness in accordance with the wavelength of the light and a first period of the first light transmission parts.

Embodiments are described hereinafter while referring to the drawings.

Note that the drawings are schematic or conceptual illustrations, and proportions in size between parts may differ from actual parts. Also, even where identical parts are depicted, mutual dimensions and proportions may be illustrated differently depending on the drawing.

Note that in the drawings and specification of this application, the same numerals are applied to elements that have already appeared in the drawings and been described, and repetitious detailed descriptions of such elements are omitted.

### First Embodiment

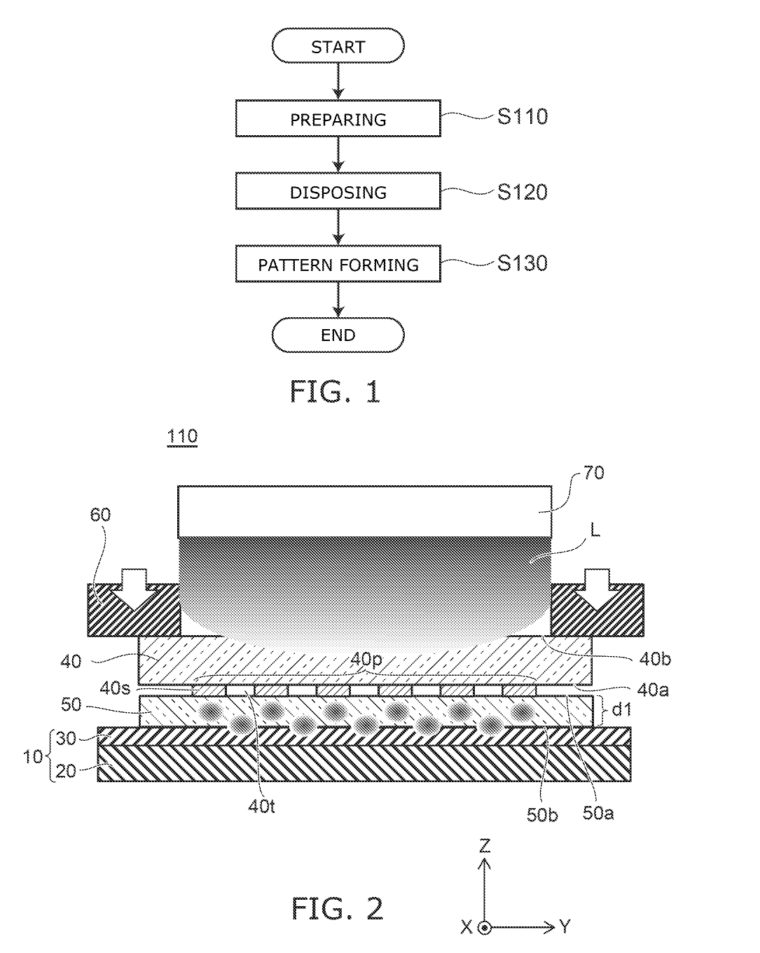

FIG. 1 is a flowchart illustrating a pattern forming method according to a first embodiment.

As illustrated in FIG. 1, in the pattern forming method according to this embodiment, a mask, a resist (member to be processed), and a spacer member (intermediate member) are prepared (step S110). The mask includes a mask pattern (first pattern portion). The mask pattern includes a plurality of light transmission parts (first light transmission parts) and shielding parts (first shielding parts). The plurality of light transmission parts have transmittivity with respect to light, and are disposed periodically. The shielding parts are provided between the plurality of light transmission parts. The light transmittance of the shielding parts is lower than the light transmittance of the light transmission parts.

The mask, the spacer member, and the resist are disposed so that the mask pattern and the spacer member are brought into contact, and the spacer member and the resist are brought into contact (step S120).

The resist is irradiated with the interference light of the Talbot interference generated by irradiating the mask pattern with light via the spacer member, and the resist is changed by the pattern in accordance with the interference light (step S130). After step S130 has been implemented, a thin film or the like that has been formed below the resist may be etched, using the resist on which the pattern has been formed.

FIG. 2 is a schematic view illustrating a light exposure device according to the first embodiment.

As illustrated in FIG. 2, a substrate 20, a resist 30 (member to be processed) formed on a surface of the substrate 20, a mask 40, a spacer member 50 (intermediate member) inserted between the resist 30 and the mask 40, a mask holder 60 for holding the mask 40, and a light source 70 are provided in a light exposure device 110.

In the light exposure device 110, the light L emitted from the light source 70 is incident on the mask 40 in the direction from the mask 40 toward the substrate 20. The resist 30 is exposed to the light L via the mask 40 and the spacer member 50.

The substrate 20 and the resist 30 correspond to a part to be processed 10. The mask 40 includes a first face 40a and a second face 40b. The spacer member 50 includes a first face 50a and a second face 50b. The light L is emitted from the light source 70, and a high voltage mercury lamp (wavelength: 365 nm), for example, is used for the light source 70. An ArF excimer laser (wavelength: 193 nm) or the like, for example, may be used for the light source 70. The light exposure device according to this embodiment is, for example, a light exposure device by the proximity method using Talbot interference.

The direction from the part to be processed 10 toward the mask 40 is defined as a Z-axis direction. One direction perpendicular to the Z-axis direction is defined as an X-axis direction. One direction perpendicular to the Z-axis direction and perpendicular to the X-axis direction is defined as a Y-axis direction.

A semiconductor substrate (wafer), for example, is used as the substrate 20. A quartz substrate or the like may be used as the substrate 20.

The resist 30 reacts with the light L irradiated from the light source 70 and is changed by a chemical action. The resist 30 includes, for example, a resin. For example, the resist 30 is a photocuring resin. As described later, a surface layer of a top coat material may be provided on the surface of the resist 30 in the Z-axis direction. A liquid may be used as the surface layer, for example. A fluorine resin may be used as the surface layer. By providing the surface layer, it is possible to suppress the adhesion of foreign matter on the surface of the resist 30. The surface damage of the resist 30 produced when the resist 30 and the spacer member 50 are separated can be suppressed by the surface layer.

The mask 40 includes a mask pattern 40p (first pattern portion) using, for example, Talbot interference. The mask pattern 40p includes a pattern corresponding to a device pattern to be formed on the substrate 20. The mask pattern 40p may also include a portion corresponding to an alignment mark pattern. The mask pattern 40p is formed on the first face 40a of the mask 40. The mask pattern 40p includes a plurality of light transmission parts 40t (first light transmission parts) having transmittivity with respect to the light L, and a plurality of shielding parts 40s (first shielding parts) provided between the light transmission parts 40t. The transmittance with respect to the light L of the light transmission parts 40t is greater than the transmittance with respect to the light L of the shielding parts 40s. The plurality of light transmission parts 40t is arranged periodically.

The mask holder 60 holds the mask 40 through contact with a portion of the second face 40b of the mask 40. The mask holder 60 is moved in the X-axis direction, the Y-axis direction, and the Z-axis direction by a drive mechanism or the like. When the mask 40 held by the mask holder 60 is moved in the −Z-axis direction, the mask 40 approaches the resist 30. When the mask 40 held by the mask holder 60 is moved in the Z-axis direction, the mask 40 moves away from the resist 30. When the light exposure process is carried out, the substrate 20, the resist 30, the spacer member 50, and the mask 40 are provided in that order in the Z-axis direction. The mask holder 60 is moved in the −Z-axis direction, and the mask pattern 40p formed on the first face 40a of the mask 40 and the first face 50a of the spacer member 50 contact, and the second face 50b of the spacer member 50 and the surface of the resist 30 contact.

The spacer member 50 is provided between the resist 30 and the mask 40 to fix a gap dl in the Z-axis direction between the mask pattern 40p and the resist 30. The gap dl corresponds to the thickness in the Z-axis direction of the spacer member 50.

A glass member such as quartz or the like, for example, can be used as the spacer member 50. A resin, for example, is used as the spacer member 50. For example, an ultra violet curing resin is used. For example, polydimethylsiloxane (PDMS) or the like may be used. The first face 50a contacts the mask pattern 40p. The second face 50b contacts the face of the resist 30 on which the exposure light is incident. The first face 50a and the second face 50b are maintained parallel to each other. By maintaining the first face 50a and the second face 50b parallel to each other, it is possible to suppress the deformation of the shape of the part to be processed 10 and the shape of the mask 40.

By providing the spacer member 50 with a constant thickness, the gap d1 is fixed. In the proximity exposure using Talbot interference, it is possible to form a pattern on the substrate 20 based on a fixed constant gap d1.

The following is a description of the proximity method using Talbot interference and the method of calculating the gap d1.

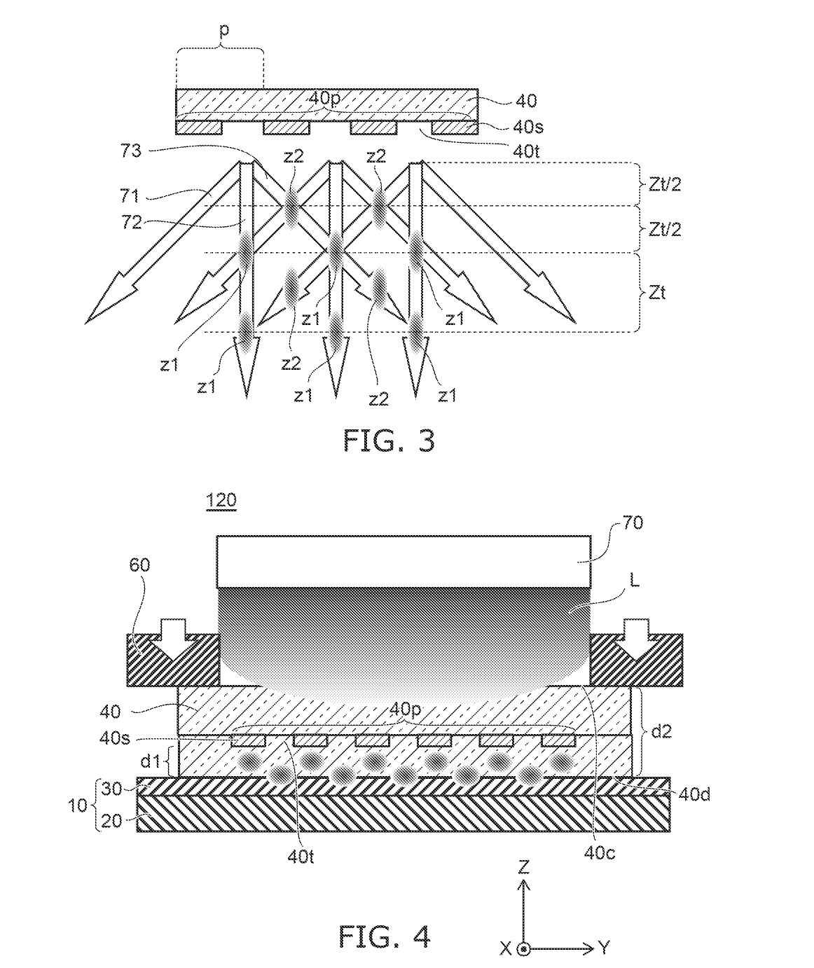

FIG. 3 is a drawing illustrating Talbot interference. As illustrated in FIG. 3, the mask pattern 40p is provided with a line and space pattern with a pattern pitch p. The mask pattern 40p includes the plurality of light transmission parts 40t having transmittivity with respect to light, and the plurality of shielding parts 40s provided between the light transmission parts 40t. The pattern pitch p corresponds to the period of the light transmission parts 40t (first period).

The mask 40 including the pattern 40p is irradiated with light from the light source. When the pattern 40p is irradiated with light, negative first order light 71, zero order light 72, and first order light 73 interference effects are produced. A plurality of image formation points z1 with high light intensity is produced in accordance with the pattern 40p based on the interference effect. The plurality of image formation points z1 is, for example, aligned at a period Zt in the direction that the light is traveling, in accordance with the pattern pitch p of the pattern 40p and the wavelength λ of the light. At positions intermediate between image formation points z1 that are adjacent to each other in the direction that the light is traveling, the light intensity is lower. In the direction perpendicular to the direction that the light is traveling (the direction in which the pattern 40p is aligned), image formation points z2 with high light intensity are produced at positions intermediate between positions with low light intensity that are adjacent to each other. The image formation points z2 with high light intensity in accordance with the pattern 40p are produced at positions at a distance of Zt/2from the image formation points z1 in the direction that the light is traveling, and at a distance of p/2 from the image formation points z1 in the direction perpendicular to the direction that the light is traveling. For example, if light exposure is carried out at the image formation points z1 and the image formation points z2, it is possible to transfer the pattern periodically at a pitch (p/2) that is half the pitch p.

The period Zt (second period) at which the image formation points z1 are repeatedly produced at a constant interval in the direction that the light is traveling in accordance with the pattern 40p is, for example, the Talbot period.

In order to produce the light intensity distribution of the image formation points z1 and the image formation points z2, the negative first order light 71, zero order light 72, and first order light 73 are produced from the pattern 40p. If the wavelength of the light source is λ, the refractive index of air is n, and the diffraction angle of the negative first order light 71 and the first order light 73 is θ1, then the pattern pitch p is

p >λ/(n·sin(θ1)) (1)

Because θ1 has a maximum of 90 degrees,

p >λ/n (2)

The refractive index n in air is equal to 1, so a pattern pitch p smaller than the wavelength A of the light from the light source is not formed. The minimum pattern pitch p is about the wavelength of the light source. For example, in the case of a line and space pattern in which the ratio of the line width and the space width is 1 to 1, it is possible to form a line pattern with width λ/2.

If the refractive index n of air is 1, and if the Talbot period Zt is approximated by calculating to the second term,

Zt=2p²/λ (3)

The position d_{z2} in the direction that the light is traveling of the image formation point z2 closest to the mask 40 is at a position ½ of the Talbot period Zt, so calculating d_{z2} from equation (3) gives,

d_{z2}=(½)·Zt=(½)·(2p²/λ)=p²/λ (4)

In order to use Talbot interference in the light exposure process, the gap dl is set in the Z-axis direction between the mask pattern 40p of the mask 40 and the resist 30, based on equation (3) or (4). The gap d1 is set based on either the Talbot period Zt or ½ the Talbot period Zt.

In this embodiment, the thickness in the Z-axis direction of the spacer member 50 provided between the mask 40 and the resist 30 (the gap d1) is based on the wavelength λ of the light source and the pattern pitch p.

In the proximity exposure using Talbot interference, the lower limit value of the gap d1 is d_{z2}. For example, when the gap d1 is n×d_{z2} (n is an integer equal to 1 or higher), the light exposure process by the proximity method using Talbot interference is efficient. In the light exposure process, the range over which Talbot interference can be efficiently used is, for example, a gap dl of not less than 0.9 times and not more than 1.1 times n times ½ the Talbot period Zt. When n is equal to 1, the range over which Talbot interference can be used in the light exposure process is, for example, a gap d1 of not less than 0.45 and not more than 0.55 times the Talbot period Zt. The upper limit value of the gap d1 is set to the range in which the light exposure process by the proximity method using Talbot interference can be carried out.

According to this embodiment, the spacer member 50 is provided between the resist 30 and the mask 40 so that the gap d1 in the Z-axis direction between the mask pattern 40p of the mask 40 and the resist 30 is fixed. By providing the spacer member 50 in this manner, it is possible to set the gap dl simply and accurately in order to use Talbot interference in the proximity exposure. In the proximity exposure using Talbot interference, the gap d1 can be accurately set, so the resist pattern can be formed on the substrate 20.

### Second Embodiment

FIG. 4 is a schematic view illustrating a light exposure device according to a second embodiment.

A substrate 20, a resist 30 formed on a surface of the substrate 20, a mask 40, a mask holder 60 for holding the mask 40, and a light source 70 are provided in a light exposure device 120. In the light exposure device 120, the light L emitted from the light source 70 is incident on the mask 40 in the direction from the mask 40 toward the substrate 20, and the resist 30 is exposed to light via the mask 40. The substrate 20 and the resist 30 correspond to a part to be processed 10. The mask 40 includes a first face 40c and a second face 40d. For example, the light exposure device according to this embodiment is a light exposure device by the proximity method using Talbot interference.

When the light exposure process is carried out, the substrate 20, the resist 30, and the mask 40 are provided in that order in the Z-axis direction. The mask holder 60 is moved in the -Z-axis direction, and a portion of the first face 40c of the mask 40 contacts the mask holder 60, the second face 40d of the mask 40 contacts the surface of the resist 30.

A mask pattern 40p (first pattern portion) using Talbot interference is included within the mask 40. In this embodiment, the mask 40 is integrated with a spacer member fixing a gap d1 set for use of Talbot interference. The thickness of the mask 40 in the Z-axis direction is equal to d2. The mask pattern 40p includes the plurality of light transmission parts 40t and the plurality of shielding parts 40s.

By providing the mask 40 integrated with the spacer member, the gap dl for using Talbot interference is fixed. In the proximity exposure using Talbot interference, it is possible to form a pattern on the substrate 20 based on a fixed constant gap d1.

FIGS. 5A to 5C are schematic cross-sectional views illustrating the fabrication of the mask.

These drawings illustrate a method of fabrication of the mask 40 integrated with a spacer member.

As illustrated in FIG. 5A, an interference layer 42 (intermediate member) corresponding to the spacer member is provided on the side of the mask pattern 40p formed on a mask substrate 41. The mask 40 is formed by, for example, depositing a light transparent film such as SiO₂ or Si₃N₄ or the like after forming the mask pattern 40p on the mask substrate 41 which has light transmittivity. The mask 40 contacts the resist 30. A high hardness diamond-like carbon or the like can be used as the mask 40.

In the example illustrated in FIG. 5B, the mask substrate 41 is not provided.

In the example illustrated in FIG. 5C, the mask 40 provided with a light shielding pattern 42p (second pattern portion) on the lower face of the interference layer 42 is illustrated. The light shielding pattern 42p includes a plurality of light transmission parts 42t (second light transmission parts) with light transmittivity, and, a plurality of shielding parts 42s (second shielding parts) provided between the light transmission parts 42t. The transmittance with respect to light of the light transmission parts 42t is greater than the transmittance with respect to light of the shielding parts 42s.

In the mask 40, the lower face of the interference layer 42 is the second face 40d that contacts the surface of the resist 30 provided on the substrate 20. A portion of the bottom face of the interference layer 42 is shielded by the light shielding pattern 42p, so a portion of the pattern of the surface of the resist 30 is shielded. When the shielding parts 42s are projected onto a plane perpendicular to the direction from the mask pattern 40p toward the interference layer 42, the shielding parts 42s are overlapped with a portion of the light transmission parts 40t.

By using the mask 40 illustrated in FIG. 5C, a pattern different from a pattern using Talbot interference is formed. For example, in Talbot interference, a periodic pattern can be formed, but by shielding a portion of the pattern formed on the surface of the resist 30, a non-periodic pattern is formed.

The following is a description of the method of fabrication of a mask 40 integrated with the spacer member.

FIGS. 6A to 6E are a flowchart illustrating the fabrication of the mask.

Using the method illustrated in these drawings, the mask 40 illustrated in FIG. 5A is fabricated.

As illustrated in FIG. 6A, a light shielding film 43 is applied onto the mask substrate 41 such as a quartz substrate or the like. Cr, CrON or the like is used as the material of the light shielding film 43.

As illustrated in FIG. 6B, a resist film 44 is applied to form the mask pattern.

As illustrated in FIG. 6C, the pattern of the resist film 44 corresponding to the mask pattern is formed by exposing the resist film 44 to light by EB lithography (mask lithography) or the like, and developing. A portion of the light shielding film 43 is etched using the pattern of the resist film 44 as a mask.

As illustrated in FIG. 6D, the pattern of the resist film 44 is removed, and the pattern of the light shielding film 43 is exposed.

As illustrated in FIG. 6E, the interference layer 42 is provided with a thickness corresponding to the gap d1 for use of Talbot interference. The interference layer 42 is formed by depositing an SiO₂ film or the like by the CVD method, or, by forming to the predetermined thickness by etching back after depositing slightly thicker.

The method illustrated in FIGS. 6A to 6E is implemented. The mask 40 illustrated in FIG. 5A is fabricated. The spacer member is integrated with the mask in this mask 40.

FIG. 5B illustrates the mask 40 with no mask substrate 41 in the mask 40 illustrated in FIG. 5A. For example, the mask 40 illustrated in FIG. 5B is fabricated by omitting the mask substrate 41 in the fabrication flow for the mask 40 in FIG. 6.

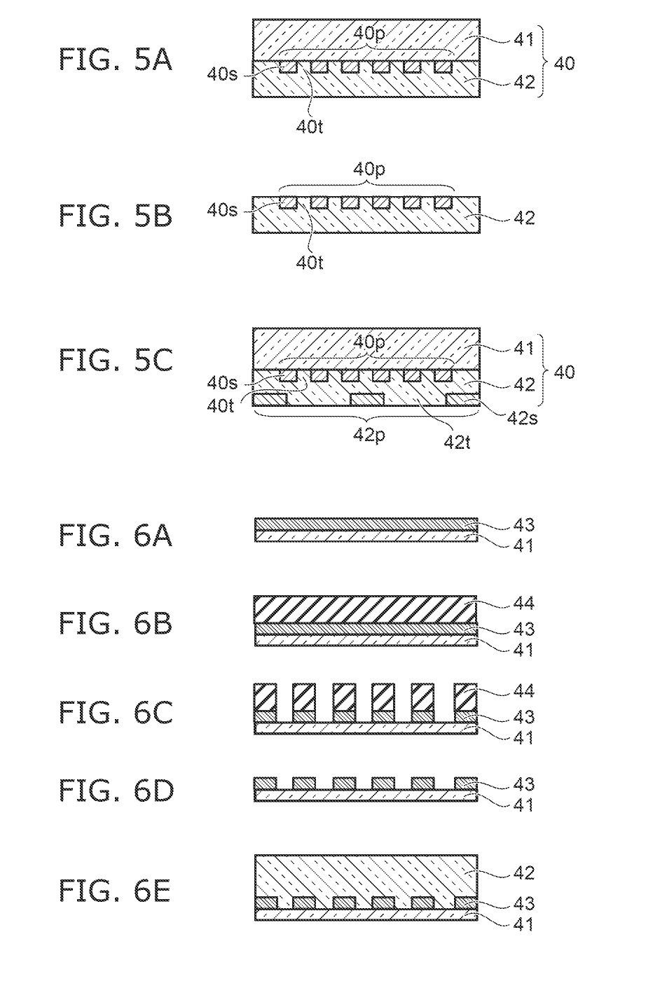

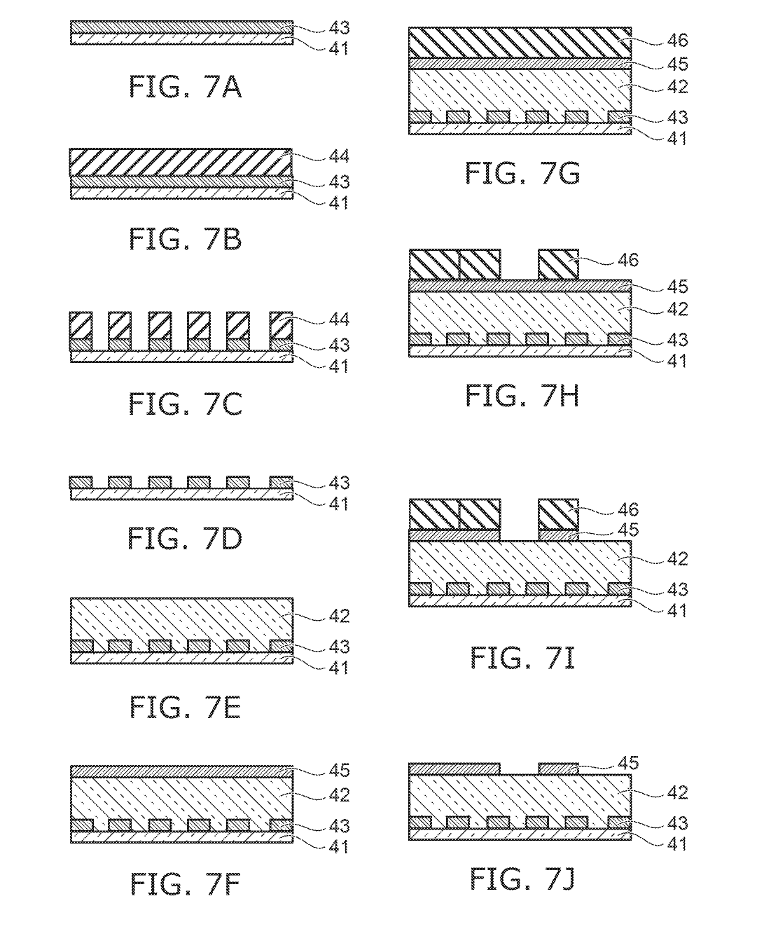

FIGS. 7A to 7J are a flowchart illustrating the fabrication of a mask.

Using the processes illustrated in these drawings, the mask 40 illustrated in FIG. 5C is fabricated. FIGS. 7A to 7E are the same as FIGS. 6A to 6E, so detailed description of these processes is omitted. By implementing the processes illustrated in FIGS. 7A to 7E, the pattern of the light shielding film 43 and the interference layer 42 are formed on the mask substrate 41.

As illustrated in FIG. 7F, a light shielding film 45 is applied onto the interference layer 42. The light shielding film 45 is applied using the sputtering method or the like.

As illustrated in FIG. 7G, a resist film 46 is applied onto the light shielding film 45.

As illustrated in FIG. 7H, the pattern of the resist film 46 that shields a portion of the mask pattern using Talbot interference is formed by exposure of the resist film 46 to light by EB lithography (mask lithography) or the like, and developing.

As illustrated in FIG. 7I, a portion of the light shielding film 45 is etched using the pattern of the resist film 46 as a mask.

As illustrated in FIG. 7J, the pattern of the resist film 46 is removed.

By implementing the processes illustrated in FIGS. 7A to 7J, the mask 40 is fabricated. In this mask 40, a light shielding pattern is provided on the lower face of the layer (interference layer 42) corresponding to the spacer member. In this example, the light shielding pattern is exposed to air. In this embodiment, a layer may be formed between the light shielding patterns made from the same material as the interference layer, so that the surface of the mask 40 will be flat.

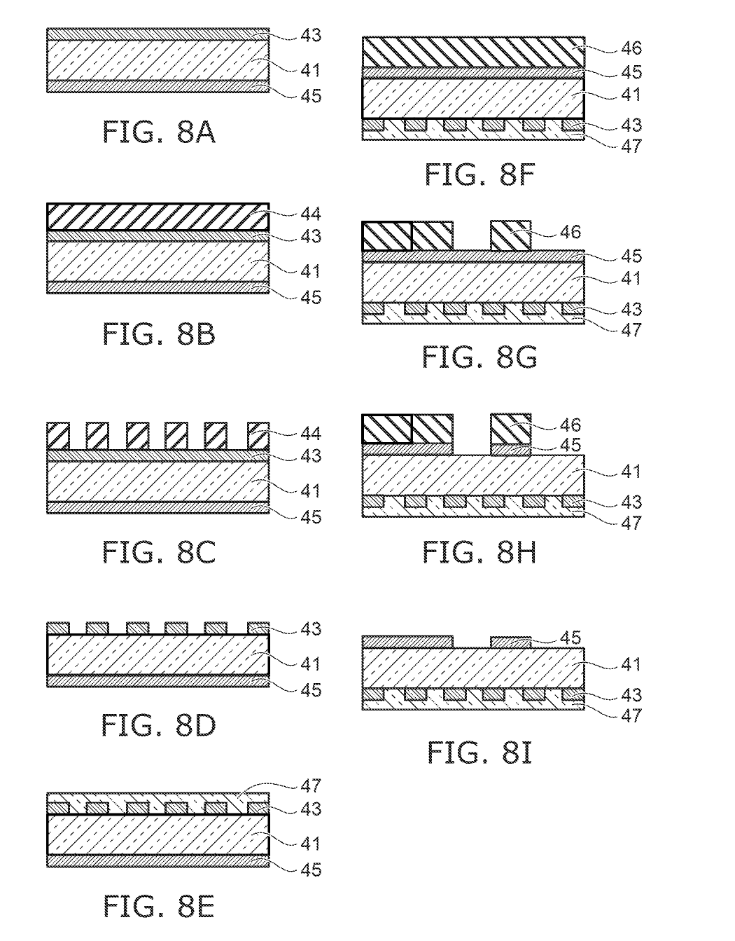

FIGS. 8A to 81 are a flowchart illustrating the fabrication of a mask.

Using the processes illustrated in these drawings, the mask 40 illustrated in FIG. 5C is fabricated.

As illustrated in FIG. 8A, the light shielding film 43 is applied to the upper face of the mask substrate 41, and the light shielding film 45 is applied to the lower face of the mask substrate 41. Cr, CrON or the like is used as the material of the light shielding film 43 and light shielding film 45.

As illustrated in FIG. 8B, the resist film 44 for forming the pattern to generate interference light is applied to the light shielding film 43.

As illustrated in FIG. 8C, the pattern of the resist film 44 is formed by exposing the resist film 44 to light by EB lithography (mask lithography) or the like, and developing.

As illustrated in FIG. 8D, a portion of the light shielding film 43 is etched using the pattern of the resist film 44 as a mask, to form the pattern of the light shielding film 43. The pattern of the light shielding film 43 corresponds to the mask pattern using Talbot interference.

As illustrated in FIG. 8E, a protective film 47 is provided on the pattern of the light shielding film 43. In this mask 40, the mask 40 is held by the mask holder 60 of the light exposure device 120 via the protective film 47. A material that transmits light of the wavelength of the light exposure, for example, is used as the material of the protective film 47. For example, at least any of a SiO₂ film, an SiN film, a polyimide film, and the like, is used as the material of the protective film 47.

As illustrated in FIG. 8F, the resist film 46 is provided on the light shielding film 45.

As illustrated in FIG. 8G, the pattern of the resist film 46 that shields a portion of the mask pattern using Talbot interference is formed by exposing the resist film 46 to light by EB lithography (mask lithography) or the like, and developing.

As illustrated in FIG. 8H, the light shielding film 45 is etched using the pattern of the resist film 46 as a mask.

As illustrated in FIG. 8I, the pattern of the resist film 46 is removed.

By implementing the processes illustrated in FIGS. 8A to 8I, the mask 40 is fabricated. In this mask 40, a light shielding pattern is provided on the lower face of the layer (mask substrate 41) corresponding to the spacer member. For example, by using a double sided light exposure device, it is possible to form the pattern of the resist film 44 as illustrated in FIG. 8C and to form the pattern of the resist film 46 as illustrated in FIG. 8G by carrying out a process once.

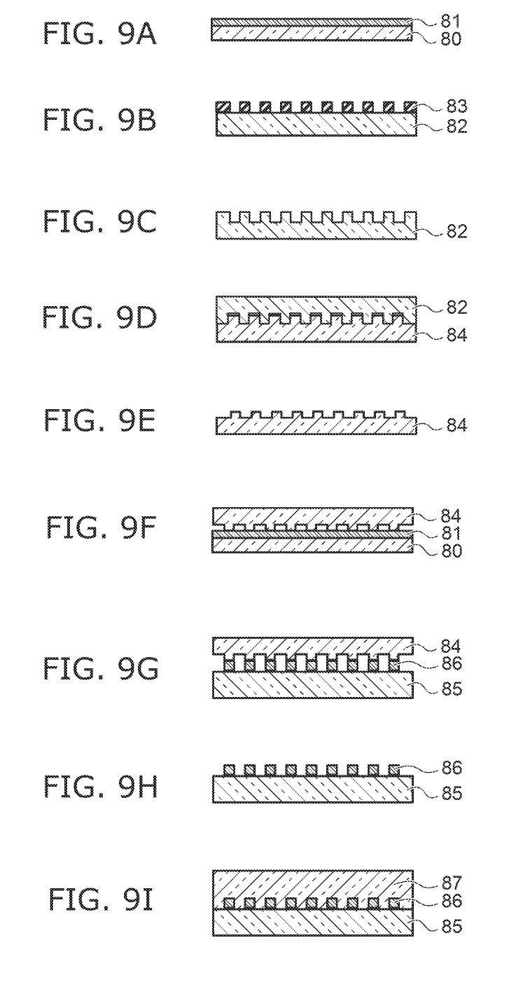

FIGS. 9A to 9I are a flowchart illustrating the fabrication of a mask.

Using the processes illustrated in these drawings, the mask 40 illustrated in FIG. 5A is fabricated. A resin or the like is used in the mask 40. The mask 40 deforms flexibly. In the method of fabricating the mask 40 as illustrated in these drawings, a light shielding pattern is formed on a film substrate using ink.

As illustrated in FIG. 9A, an ink film 81 is applied to a substrate 80 such as an Si wafer or the like. The material used in the ink film 81 has low transmittance with respect to exposure light for generating Talbot interference light. For example, ink used for printing such as gravure ink or the like may be used as the ink. Ink in which metal particles or the like are dispersed may be used.

In FIGS. 9B to 9E, a mold (plate) for transferring the ink is fabricated. As illustrated in FIG. 9B, if a substrate 82 is used as the original plate, a pattern of a resist film 83 is formed on the substrate 82.

As illustrated in FIG. 9C, etching is carried out, and the original plate (substrate 82) is fabricated with the convex and concave portions reversed relative to the mask pattern. As illustrated in FIG. 9D, the original plate is pressed into a mold 84 that includes a resin such as PDMS or the like.

As illustrated in FIG. 9E, when the original plate is separated from the PDMS, convex and concave portions are formed on the surface of the PDMS corresponding to the shape of the mask pattern. As a result of the processes illustrated in FIGS. 9B to 9E, the mold 84 having convex and concave portions is fabricated.

As illustrated in FIG. 9F, the mold 84 is brought into contact with the ink film 81 on the substrate 80 fabricated in FIG. 9A. In this way, the ink is transferred to the convex portions of the mold 84.

As illustrated in FIG. 9G, the ink transferred to the mold 84 is brought into contact with a film substrate 85 such as a polyethylene terephthalate (PET) film or the like. When the ink is brought into contact with the film substrate 85, preferably a UV ozone process, a plasma process, application of an adhesive layer or the like is carried out on the surface of the film substrate 85. In this way, the adhesion of the ink to the surface of the film substrate 85 is improved.

As illustrated in FIG. 9H, the mold 84 is separated from the film substrate 85. In this way, the ink 86 remains on the film substrate 85. The ink 86 is hardened by a method based on the type of ink 86 used. To harden the ink 86, a process such as at least one of irradiation with UV light and heating is carried out.

As illustrated in FIG. 9I, an interference layer 87 with a thickness corresponding to the gap dl for using Talbot interference is applied. The interference layer 87 is formed using a glass material (SOG) that can be applied, an organic film or the like.

By implementing the processes illustrated in FIGS. 9A to 9I, the mask 40 as illustrated in FIG. 5A is fabricated. The spacer member is integrated with the mask in this mask 40.

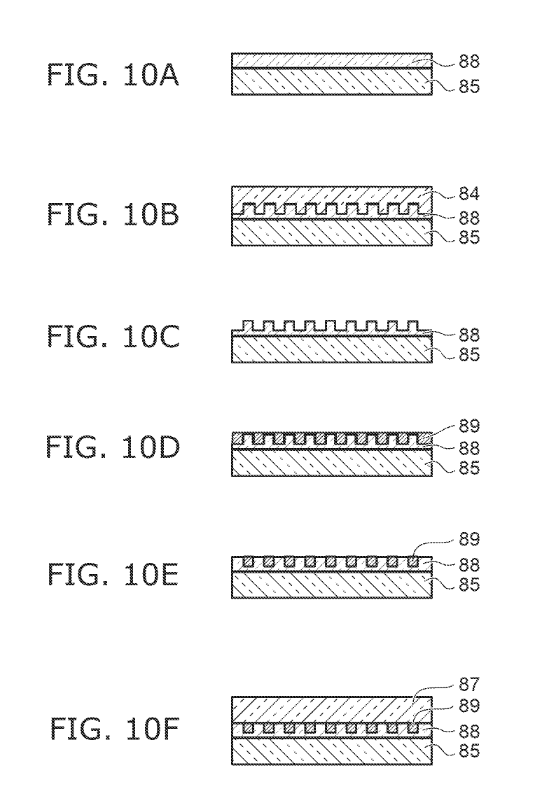

FIGS. 10A to 10F are a flowchart illustrating the fabrication of a mask.

Using the processes illustrated in these drawings, the mask 40 illustrated in FIG. 5A is fabricated.

As illustrated in FIG. 10A, an intermediate film 88 is formed on the film substrate 85. A UV hardening resin film or a thermosetting resin film or the like is used as the intermediate film 88.

As illustrated in FIG. 10B, the mold 84 fabricated by FIGS. 9B to 9E is pressed into the intermediate film 88, and a convex and concave pattern is formed on the intermediate film by thermal imprinting, UV imprinting or the like.

As illustrated in FIG. 10C, the mold 84 is separated from the intermediate film 88, and the convex and concave pattern formed on the intermediate film 88 is exposed. The concave portions within the convex and concave pattern correspond to the mask pattern for using Talbot interference.

As illustrated in FIG. 10D, a light shielding material 89 is applied to the convex and concave pattern, and the concave portions are filled with the light shielding material 89. For example, ink may be used as the light shielding material 89.

As illustrated in FIG. 10E, the light shielding material 89 overflowed on the surface is removed so that the light shielding material 89 is formed selectively in the concave portions of the intermediate film 88. Then, the light shielding material 89 is hardened.

As illustrated in FIG. 10F, the interference layer 87 is formed on the intermediate film 88 and the light shielding material 89.

By implementing the processes as illustrated in FIGS. 10A to 10F, the mask 40 integrated with the spacer member as illustrated in FIG. 5A is fabricated.

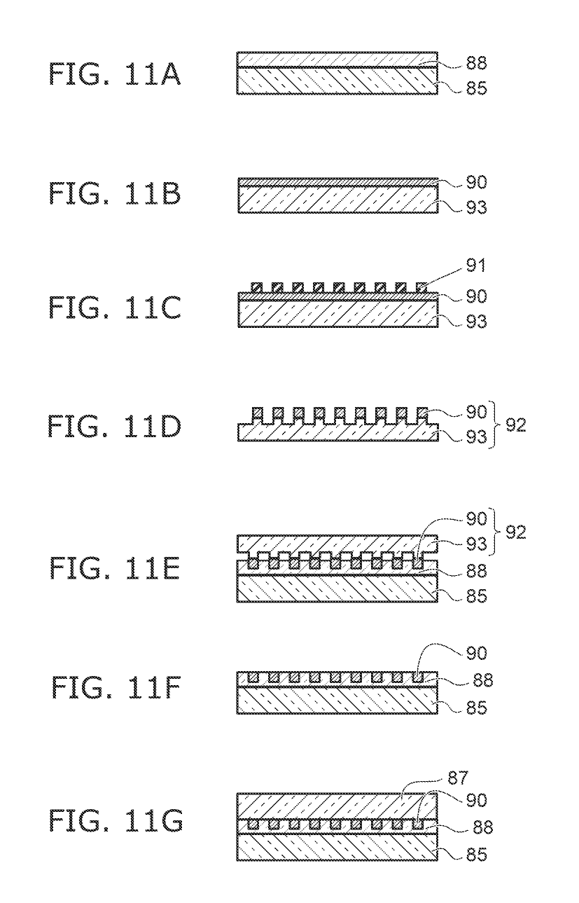

FIGS. 11A to 11G are a flowchart illustrating the fabrication of a mask.

Using the processes illustrated in these drawings, the mask 40 illustrated in FIG. 5A is fabricated.

As illustrated in FIG. 11A, the intermediate film 88 is formed on the film substrate 85.

In the processes illustrated in FIGS. 11B to 11D, a mold 92 with an embedded light shielding material pattern is fabricated by a vacuum process. As illustrated in FIG. 11B, a light shielding film 90 is formed on a mold substrate 93 (for example, an Si wafer). A metal film such as, for example, carbon, chromium, tungsten, and the like is used as the light shielding film 90.

As illustrated in FIG. 11C, a pattern of a resist film 91 is formed on the light shielding film 90 for forming a pattern of the light shielding film 90.

As illustrated in FIG. 11D, a portion of the light shielding film 90 and a portion of the mold substrate 93 are etched using the pattern of the resist film 91 as a mask. The mold 92 is fabricated by the processes illustrated in FIGS. 11B to 11D.

As illustrated in FIG. 11E, the light shielding material pattern of the mold 92 is pressed into the intermediate film 88 on the film substrate 85 fabricated by the process illustrated in FIG. 11A.

As illustrated in FIG. 11F, the mold 92 is separated from the intermediate film 88 with the light shielding material pattern remaining embedded in the intermediate film 88. The light shielding material pattern is formed in the intermediate film 88.

As illustrated in FIG. 11G, by applying and forming the interference layer 87 on the intermediate film 88, the mask 40 integrated with the spacer member as illustrated in FIG. 5A is fabricated.

FIGS. 6A to 11G illustrate several examples of the fabrication of the mask 40 integrated with the spacer member. For example, an example in which a mask pattern of Cr or the like is formed on a quartz substrate, and an example in which a mask pattern made from ink or the like is formed on a film substrate are illustrated. The mask 40 is classified as a quartz mold type mask, a flexible mold type mask, or a quartz substrate resin mold type mask, depending on the materials used in the mask 40. The resolution of the mask pattern is good in a quartz mold type mask. With the flexible mold type mask, the cost of fabrication of the mask can be suppressed. With the quartz substrate resin mold type mask, a comparatively large area can be exposed to light at one time.

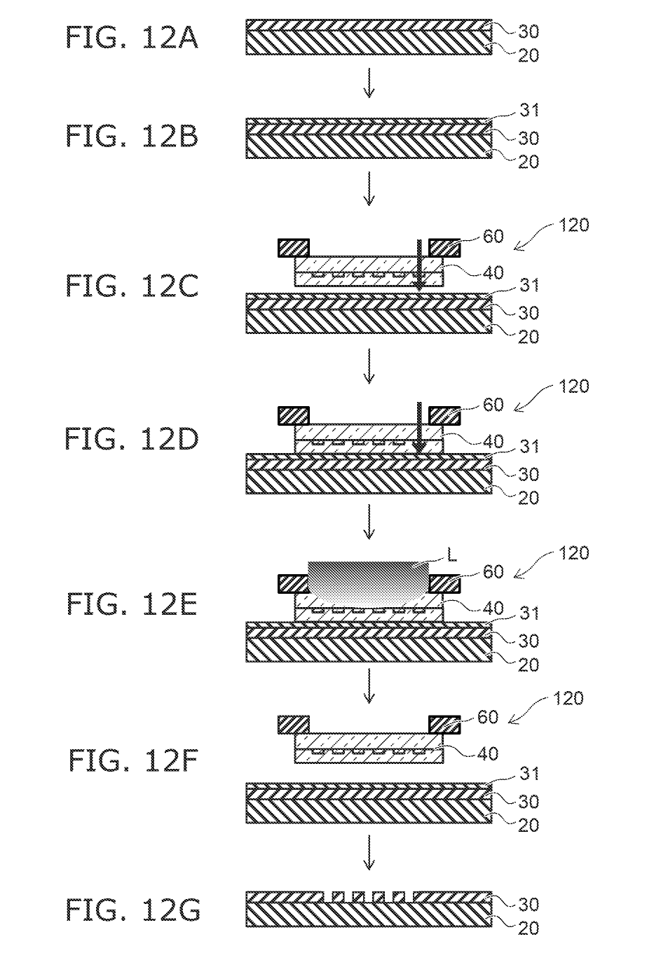

FIGS. 12A to 12G are a flowchart illustrating a pattern forming method according to a second embodiment.

In this example, a mask 40 integrated with the spacer member is used in the light exposure process.

As illustrated in FIG. 12A, the resist 30 is applied to the substrate 20. If necessary, pre-baking may be carried out.

As illustrated in FIG. 12B, a surface layer 31 which is a top coat material is applied to the resist 30. In this example, the surface layer 31 is a liquid, for example. A fluorine resin may be used in the surface layer 31. By providing the surface layer 31 on the resist 30, it is possible to suppress the adhesion of foreign matter on the surface of the resist 30, for example. In addition, it is possible to suppress damage to the surface of the resist 30 in the process of demolding, for example. The surface layer 31 may be provided on the face of the mask 40 that contacts the resist 30 (the second face 40d).

As illustrated in FIG. 12C, the object to be processed, which is the resist 30 and the surface layer 31 deposited and applied in that order on the substrate 20, is set in the light exposure device 120. After setting the object to be processed in the light exposure device 120, the mask holder 60 is moved in at least one direction of the X-axis direction, the Y-axis direction, and the Z-axis direction, and rough positioning (rough alignment) between the object to be processed and the mask 40 is carried out.

As illustrated in FIG. 12D, the mask holder 60 is moved in the Z-axis direction, and the mask 40 and the resist 30 on the surface of which the surface layer 31 has been applied are brought into contact. If the positioning between the object to be processed and the mask 40 is shifted due to the contacting operation, positioning (alignment) is carried out. The surface layer 31 is provided on the resist 30, so even when the mask 40 and the resist 30 are in contact, the positioning (alignment) can be carried out between the object to be processed and the mask 40 without damaging the resist 30.

As illustrated in FIG. 12E, the light L emitted from the light source is incident on the mask 40 in the direction from the mask 40 toward the substrate 20, and the resist 30 is exposed to the light via the mask 40.

As illustrated in FIG. 12F, the mask holder 60 is moved in the Z-axis direction, and the mask 40 is separated (demolded) from the object to be processed.

As illustrated in FIG. 12G, the resist 30 is developed to obtain the pattern. The surface layer 31 is removed when developing and rinsing.

According to this embodiment, by providing the mask 40 integrated with the spacer member, the gap dl for using Talbot interference is fixed. By using this type of mask 40, for example, it is possible to simply and accurately set the gap d1 between the mask 40 and the resist 30 in the proximity exposure using Talbot interference. In the proximity exposure using Talbot interference, the gap dl between the mask 40 and the resist 30 can be accurately set, so the resist pattern can be formed on the substrate 20.

According to this embodiment, it is possible to provide a mask and pattern forming methods that enable highly accurate patterns to be simply formed.

Embodiments of the invention with reference to examples were described above. However, the embodiments of the invention are not limited to these examples. The scope of the invention includes all cases in which, for instance, a person skilled in the art makes use of publicly known information to appropriately select the specific configuration of each element used in the mask and pattern forming method in implementing the invention, provided that the obtained effects are similar.

Moreover, combinations of two or more components in the specific examples within a technically feasible range are also included in the scope of the invention as long as the spirit of the invention is included.

In addition, any mask and pattern method, which those skilled in the art can carry out by making appropriate design modifications based on the mask and the pattern method described above as the embodiments of the invention, are also in the scope of the invention as long as the spirit of the invention is included.

Also, within the scope of principles of the invention, various changes and modifications will be readily made by those skilled in the art. Accordingly, it will be appreciated that such changes and modifications also fall within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Moreover, above-mentioned embodiments can be combined mutually and can be carried out.

What is claimed is:

1. A mask, comprising:
a first pattern portion including a plurality of first light transmission parts disposed periodically and having transmittivity with respect to light, and first shielding parts provided between each of the plurality of first light transmission parts and having a transmittance with respect to the light lower than a transmittance of the plurality of first light transmission parts; and
an intermediate member provided on the first pattern portion, the intermediate member having a thickness in accordance with the wavelength of the light and a first period of the first light transmission parts.

2. The mask according to claim 1, wherein the thickness is based on a second period of interference light due to Talbot interference in the first pattern portion.

3. The mask according to claim 2, wherein the thickness is not less than 0.9 times and not more than 1.1 times an integer equal to or greater than 1 times ½ the second period.

4. The mask according to claim 2, wherein the thickness is not less than 0.45 times and not more than 0.55 times the second period.

5. The mask according to claim 1, wherein the intermediate member includes quartz.

6. The mask according to claim 1, wherein the intermediate member includes resin.

7. The mask according to claim 1, further comprising a substrate that is transparent to the light, wherein
the first pattern portion is disposed between the intermediate member and the substrate.

8. The mask according to claim 7, wherein the substrate includes quartz.

9. The mask according to claim 7, wherein the substrate includes at least one of polyethylene terephthalate, polyethylene naphthalate, polyimide, and acrylic.

10. The mask according to claim 1, further comprising a second pattern portion, wherein
the intermediate member is disposed between the second pattern portion and the first pattern portion,
the second pattern portion has transmittivity with respect to the light, and
the second pattern portion includes a second light transmission part, and a second light shielding part having transmittance with respect to the light lower than the transmittance of the second light transmission part.

11. The mask according to claim 10, wherein the second light shielding part overlaps a portion of the plurality of first light transmission parts when projected onto a plane perpendicular to the direction from the first pattern portion toward the intermediate member.

12. A pattern forming method, comprising:
disposing the intermediate member of the mask described in claim 1 in contact with a member to be processed; and
irradiating the member to be processed with interference light of Talbot interference generated by irradiating the first pattern portion with light via the intermediate member, and changing the member to be processed in a pattern in accordance with the interference light.

13. The method according to claim 12, wherein the member to be processed includes a surface layer, and
the surface layer is disposed so as to contact the intermediate member in the disposing.

14. A pattern forming method, comprising:
preparing a mask, the mask including a first pattern portion including a plurality of first light transmission parts disposed periodically and having transmittivity with respect to light, and first shielding parts provided between each of the plurality of first light transmission parts and having a transmittance with respect to the light lower than a transmittance of the plurality of first light transmission parts, a member to be processed, and an intermediate member;
disposing the mask, the intermediate member, and the member to be processed so that the first pattern portion is in contact with the intermediate member and the intermediate member is in contact with the member to be processed; and
irradiating the member to be processed with interference light of Talbot interference generated by irradiating the first pattern portion with light via the intermediate member, and changing the member to be processed in a pattern in accordance with the interference light.

15. The method according to claim 14, wherein the thickness of the intermediate member is based on a second period of the interference light due to Talbot interference.

16. The method according to claim 15, wherein the thickness of the intermediate member is not less than 0.9 times and not more than 1.1 times an integer equal to or greater than 1 times ½ the second period.

17. The method according to claim 15, wherein the thickness of the intermediate member is not less than 0.45 times and not more than 0.55 times the second period.

18. The method according to claim 14, wherein the intermediate member includes quartz.

19. The method according to claim 14, wherein the intermediate member includes resin.

20. The method according to claim 14, wherein the member to be processed includes a surface layer, and
in the disposing, the surface layer is disposed so as to contact the intermediate member.
